(19) United States
(12) Patent Application Publication
(10) Pub. No.: US 2013/0065385 A1
(43) Pub. Date: Mar. 14, 2013

(54) METHOD FOR PREPARING SPACER TO REDUCE COUPLING INTERFERENCE IN MOSFET

(71) Applicants: Xiaolu HUANG, Shanghai (CN); Chaos ZHANG, Shanghai (CN); Yuwen CHEN, Shanghai (CN)

(72) Inventors: Xiaolu HUANG, Shanghai (CN); Chaos ZHANG, Shanghai (CN); Yuwen CHEN, Shanghai (CN)

(73) Assignee: SHANGHAI HUALI MICROELECTRONICS CORPORATION, Shanghai (CN)

(21) Appl. No.: 13/339,422

(22) Filed: Dec. 29, 2011

(30) Foreign Application Priority Data
Sep. 8, 2011 (CN) 201110266253.X
Oct. 17, 2011 (CN) 201110314342.7

(51) Int. Cl. H01L 21/28

(52) U.S. Cl. 438/591; 257/E21.21

(57) ABSTRACT

The present invention provides a method for preparing spacer to reduce coupling interference in MOSFET, which includes the steps of: forming a gate oxide layer on the semiconductor substrate; forming a gate on the gate oxide layer; and depositing a low-K dielectric material on the gate and the semiconductor substrate, and doping with carbon during deposition to form a carbon-containing low-K dielectric layer and then forming the spacer by an etching process.

### CROSS REFERENCE TO RELATED APPLICATIONS

This application is based upon and claims the benefit of priority from the prior Chinese Patent Application No. 201110266253.x filed on Sep. 9, 2011 and the prior Chinese Patent Application No. 201110314342.7 filed on Oct. 17, 2011 with Chinese State Intellectual Property Office, under 35 U.S.C. §119. The content of the above prior Chinese Patent Applications is incorporated herein by reference in its entirety.

### FIELD OF THE INVENTION

The present invention relates to the field of semiconductor and more particularly, to a Complementary Metal Oxide Semiconductor (CMOS) device structural unit and a method for preparing spacer to reduce coupling interference in Metal-Oxide-Semiconductor Field Effect Transistor (MOSFET).

### BACKGROUND OF THE INVENTION

After rapid development in decades of years from the advent of the first transistor, the lateral dimension and the longitudinal dimension of the transistor both rapidly decrease. According to the prediction of the International Technology Roadmap for Semiconductors (ITRS) on 2004, the characteristic dimension of transistor will reach 7 nm in 2018. The continuous decrease in dimension not only improves the performance (speed) of transistor continuously, but also enables us to integrate more devices in the same area of a chip, so that the integrated circuit is becoming more powerful, and the cost per function is also decreased.

However, the continuous decrease in the characteristic dimension of semiconductor device is also accompanied with a series of challenges. When the characteristic dimension of semiconductor device enters deep sub-micron scale, the short channel effect (SCE) of semiconductor device becomes more serious, so that the performance of semiconductor device is degraded. SCE refers to a common phenomenon during shrinkage in the channel length of a CMOS device. It may cause drifting of threshold voltage, punch-through of the source/drain, drain induced barrier lower (DIBL) (under high drain voltage), or the like. In a severe case, it may lead to failure in performance of CMOS device.

For example, a currently common non-volatile memory is of a floating gate type or a trap charge capturing type. The gate of a floating gate type device is a stacked gate comprising a floating gate and a control gate, in which a charge blocking layer is arranged between the floating gate and the control gate, and a tunneling oxide layer is provided between the floating gate and the channel of the device. The control gate is connected with a word line, the floating gate, which is commonly formed by poly-silicon, is used to store charges, and the control gate is used to control the writing/reading operation. In contrast, in the trap charge capturing type device, a charge trapping layer is used to replace the floating gate. For example, in a Silicon-Oxide-Nitride-Oxide-Semiconductor (SONOS) device, silicon nitride is applied as the charge trapping layer.

Due to the presence of the floating gate or the charge trapping layer in the non-volatile memory cell, when the non-volatile memory cell is scaled down continuously and the distance between any two word lines becomes too small, an issue regarding coupling interference occurs. Such an issue causes drifting of threshold voltage of the memory cell, which poses a serious issue that the process of integrated circuit products at a high level node like 45 nm or less.

SCE can be interpreted by a charge sharing model proposed by Yau, i.e., when the channel becomes short, the ratio between charges in the channel depletion region shared by the source liner and drain liner PN junction and the total charges in channel will increase, so that the gate control capability decreases.

On basis of the formula for drifting of threshold voltage derived from the charge sharing model:

$$Δ {V}_{th , l} = {V}_{th} ( long \text{-} channel ) - {V}_{th} ( short \text{-} channel ) = \frac{Δ {Q}_{l}}{{C}_{ox}} = \frac{{Q}_{b}}{{C}_{ox}} \cdot \frac{{X}_{j}}{L} \sqrt{1 + \frac{2 {X}_{dm}}{{X}_{d}}} -$$

it can be seen that there are three types of conventional methods for suppressing SCE (by modifying three parameters indicated in the above formula, respectively):

1) reducing the thickness of gate dielectric layer tox,

2) reducing the channel doping concentration Nb, and

3) reducing the junction depth Xj of the source-substrate and drain-substrate PN junctions.

Here, as for the scheme of modifying tox, since there exists an exponential relation between the dielectric layer tunneling current and the thickness of the oxide layer, the thickness of the gate dielectric layer cannot be decreased infinitely. For instance, as for a conventional SiO₂ or SiON dielectric layer, when the thickness decreases to 1 nm, the device may suffer from complete failure.

In the prior art, as for the advanced nanometer scale device, a high-K material with a large dielectric constant, like HfO₂, ZrO₂, Al₂O₃, or the combination thereof has been introduced as the gate dielectric layer, so that an equivalent EOT can be achieved for a relatively large thickness.

However, the above charge sharing model does not take into account the effect in which the electric field at the edge of the source/drain influences the channel through capacitive coupling of spacer in a CMOS device. Such an effect is not evident when the dielectric layer of SiO₂ or SiON is relatively thin. If a thick gate dielectric layer of a high-K material is applied, such an effect on the CMOS device is more pronounced, and in extreme cases the CMOS device may degrade in properties.

Theoretically, there are two approaches to reduce such an effect, one of which is to increase the thickness of spacer, and the other one of which is to decrease the dielectric constant of spacer. Of these two approaches, the former is unfavorable to increase the integration density. The latter is an effective method to decrease the coupling capacitance of spacer, so as to decrease the effect in which the electric field at the edge of the source/drain influences the channel through capacitive coupling of spacer.

However, the spacer material of the current CMOS device (e.g., the spacer material in a non-volatile device) still sticks to the conventional spacer types, which is generally classified into:

(i) an ONO type, in which SiO₂ is arranged on the inner side and outer side, with Si₃N₄ arranged therebetween,

(ii) a NO type, in which Si₃N₄ is arranged on the inner side, and SiO₂ on the outer side;

(iii) an ON type, in which SiO₂ is arranged on the inner side, and Si₃N₄ on the outer side,

(iv) the spacer only comprises SiO₂, and

(v) the spacer only comprises Si₃N₄.

Namely, SiO₂, Si₃N₄, or the combination thereof is used the spacer material, in which SiO₂ has a relative dielectric constant of 3.9, and Si₃N₄ has a relative dielectric constant twice that of SiO₂. When the non-volatile memory cell is scaled down continuously and the distance between any two word lines becomes too small, the issue of coupling interference will become more serious.

Therefore, it is an urgent issue in the industry to decrease the relative dielectric constant of spacer material in the CMOS device, especially in a device with a high-K gate dielectric layer, so as to reduce coupling interference.

### SUMMARY OF THE INVENTION

In view of the issue regarding coupling interference in the prior art CMOS device, the present invention proposes a new method for reducing coupling interference. Namely, by decreasing the relative dielectric constant of a spacer material in the CMOS device, the coupling interference is reduced and the integration density of the CMOS device is significantly increased.

To achieve the above object, the technical solution of the present invention comprises a method for preparing spacer to reduce coupling interference in MOSFET, the spacer is included in a function unit of a CMOS device, the method comprises the steps of:

step 1: forming a gate oxide layer on the semiconductor substrate,

step 2: forming a gate on the gate oxide layer, and

step 3: depositing a low-K dielectric material on the gate and the semiconductor substrate, doping with carbon during deposition to form a carbon-containing low-K dielectric layer, and then forming the spacer by an etching process.

According to the concept of the present invention, the low-K dielectric layer of the spacer is formed by SiO₂, Si₃N₄, or the combination thereof, and SiO₂ or Si₃N₄ is doped with carbon.

According to the concept of the present invention, the low-K dielectric layer of the spacer has a relative dielectric constant of 1.8-3.5.

According to the concept of the present invention, the step 3 particularly comprises the steps of:

step 31: forming a microporous carbon-doped low-K dielectric inner layer on the gate and the semiconductor substrate by deposition, and forming a first spacer layer from the inner layer by a self-aligning etching process, and

step 32: depositing on the first spacer layer an outer layer of SiO₂, Si₃N₄, or the combination thereof, and forming a second spacer layer from the outer layer by a self-aligning etching process.

According to the concept of the present invention, the inner layer is formed by SiO₂, Si₃N₄, or the combination thereof, and SiO₂ or Si₃N₄ is doped with carbon.

According to the concept of the present invention, the inner layer is formed by amorphous carbon.

According to the concept of the present invention, the top of the inner spacer layer formed in step 31 is lower than that of the outer spacer layer formed in step 32.

According to the concept of the present invention, the outer layer of the low-K dielectric layer is formed by SiO₂, Si₃N₄, or the combination thereof.

According to the concept of the present invention, the outer layer of the spacer in the low-K dielectric layer is formed by SiO₂, Si₃N₄, or the combination thereof, and SiO₂ or Si₃N₄ is doped with carbon.

According to the concept of the present invention, the material of the gate oxide layer comprises any one of HfO₂, ZrO₂, Al₂O₃, or the combination thereof.

According to the concept of the present invention, the function unit is a non-volatile memory cell of a floating gate type; wherein the gate comprises from bottom to top a tunneling oxide layer, a floating gate layer, a charge blocking layer, and a control gate layer.

According to the concept of the present invention, the function unit is a non-volatile memory cell of a trap charge capturing type; wherein the gate comprises from bottom to top a tunneling oxide layer, a charge trapping layer, a charge blocking layer, and a control gate layer.

According to the concept of the present invention, the gate oxide layer is a thick high-K gate dielectric layer.

In the method described above, the spacer material is doped with carbon during deposition, so that the dielectric constant of the spacer material is significantly decreased. As a result, the effect in which the electric field at the edge of the source/drain influences the channel through capacitive coupling of spacer can be reduced in a CMOSFET with a thick high-K gate, the short channel effect in a MOSFET with a thick high-K gate dielectric layer is effectively suppressed, and the performance of the CMOS device is improved. Furthermore, the method is simple and convenient to carry out.

It is particularly worth mentioning that, in case that the present invention is applied to prepare a non-volatile memory cell of a CMOS device, as compared with the non-volatile memory in the prior art, the coupling interference in a non-volatile memory is eliminated, and the Interfering Reduction Operation (IRO) related additional circuits are omitted, so that the design of memory circuit is efficiently simplified, and the integration level of the non-volatile memory as well as the reading/writing speed of the memory are improved.

### BRIEF DESCRIPTION OF THE DRAWINGS

FIG. 1 is a schematic diagram showing a CMOS device structure according to a preferred embodiment of the present invention

FIG. 2 is a schematic flow chart showing a method for preparing spacer to reduce coupling interference in MOSFET according to a preferred embodiment of the present invention

FIG. 3 is a schematic diagram showing the structure of a non-volatile memory cell according to a preferred embodiment of the present invention.

### DETAILED DESCRIPTION OF THE EMBODIMENTS

Representative embodiments reflecting the features and advantages of the present invention will be described in details hereinafter. It is understood that modifications to various embodiments of the present invention are possible without departing from the scope of the present invention, and that the description and illustration are descriptive in nature but not intended to limit the present invention.

The above-mentioned and other technical features and beneficial effects of the present invention will be described in details hereinafter by reference with the preferred embodiments as well as FIGS. 1-3.

Reference is made to FIG. 1, which is a structural diagram showing a function unit of a CMOS device structure according to a preferred embodiment of the present invention. In this embodiment, the function unit of the CMOS device comprises a semiconductor substrate 100, a gate oxide layer 101 formed on the semiconductor substrate 100, a gate 102 formed on the gate oxide layer 101, spacer 103 formed on both sides of the gate 102, and source/drain regions 104/105 formed in the semiconductor substrate 100 on both sides of the gate 102. Here, the gate oxide layer 101 is a thick high-K gate dielectric layer, while the spacer 103 is a carbon-containing material and includes a low-K dielectric layer with a relatively low dielectric constant.

According to an embodiment of the present invention, the spacer 103 is a low-K dielectric layer, so that the effect in which the electric field at the edge of the source/drain influences the channel through capacitive coupling of spacer 103 can be reduced in a CMOS device with a thick high-K gate. In this way, the short channel effect in a CMOS device with a thick high-K gate dielectric can be effectively suppressed, thus improving the performance of the CMOS device.

In a preferred embodiment of the present invention, the material used for the low-K dielectric layer of spacer 103 can comprise SiO₂ doped with carbon, Si₃N₄ doped with carbon, or the combination thereof. The relative dielectric constant of the low-K dielectric layer may be in the range of 1.8-3.5. For instance, when the material of the spacer 103 is SiO₂, the relative dielectric constant of the low-K dielectric layer which is doped with carbon may be 2.7 or less. In addition, in general, the material of the gate oxide layer 101 may be any one of HfO₂, ZrO₂, Al₂O₃, or the combination thereof.

It is noted that, in the CMOS device structure proposed in embodiments of the present invention, the gate oxide layer may/may not be a thick high-K gate dielectric layer. However, as far as the final effects are concerned, it is preferred to use a thick high-K gate dielectric layer in the present invention.

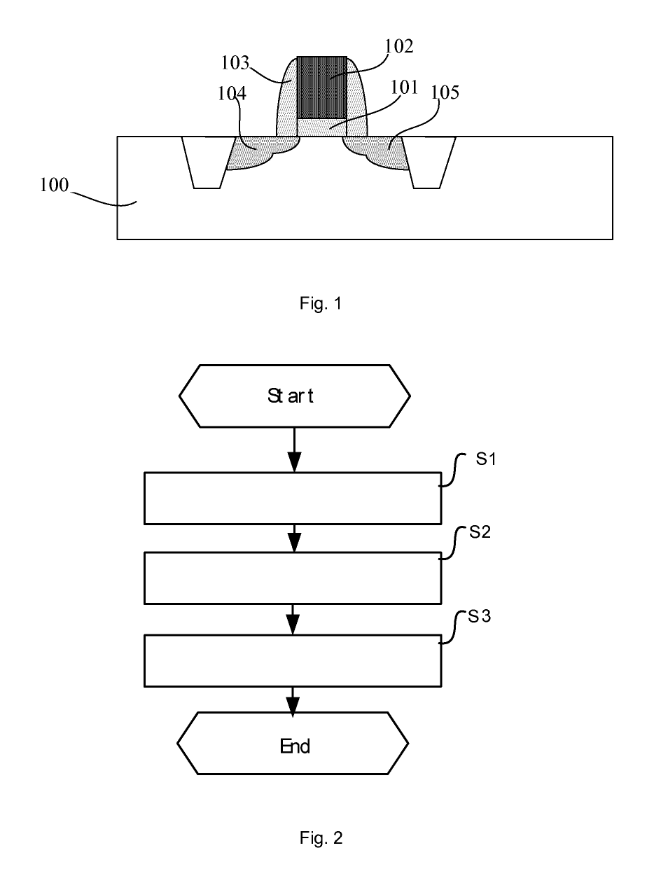

The method for preparing low-K spacer to reduce coupling interference in MOSFET according to the present invention, as shown in FIG. 2, may comprise the steps of:

step 1: forming a gate oxide layer on the semiconductor substrate,

step 2: forming a gate on the gate oxide layer, and

step 3: depositing a low-K dielectric material on the gate and the semiconductor substrate, and doping with carbon during deposition to form a carbon-containing low-K dielectric layer, and then forming the spacer by an etching process.

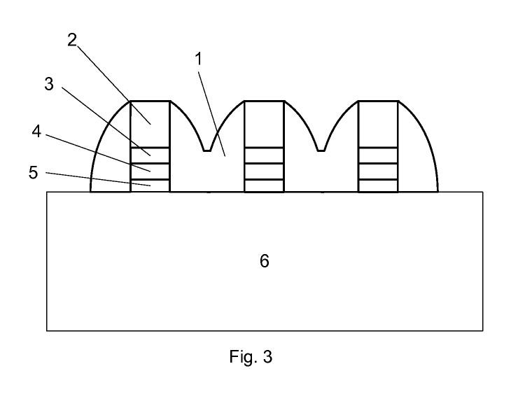

The processes for preparing the gate oxide layer and the gate in step 1 and step 2 may be accomplished by those used in the prior art. An example is shown in FIG. 3, which illustrates another kind of function unit in a CMOS device, i.e., a non-volatile memory cell. It can be seen that the non-volatile memory cell may be of a floating gate type or a trap charge capturing type, which distinguishes from a common MOS device only in that the gate has a multiple-layer structure. In case of the non-volatile memory cell of a floating gate type, a tunneling oxide layer 5, a floating gate layer 4, a charge blocking layer 3, and a control gate layer 2 are deposited sequentially on the semiconductor substrate 6. The excessive portions of the resulting structure are etched away to form the above-mentioned multiple-layer structure gate. While for the non-volatile memory cell of a trap charge capturing type, a tunneling oxide layer 5, a charge trapping layer 4, a charge blocking layer 3, and a control gate layer 2 are deposited on a semiconductor substrate, and the excessive portions are etched away to form the multiple-layer structure gate. Therefore, the same spacer and the effect thereof can be achieved by applying the method for preparing spacer to reduce coupling interference in MOSFET according to the present invention to a common MOS device and a non-volatile memory cell. In this disclosure, the method of the present invention is only described by taking a common MOS device as an example.

The processing steps according to the present invention in step 3 of depositing a low-K dielectric material on the gate and the semiconductor substrate, and doping with carbon during deposition to form a carbon-containing low-K dielectric layer, will be described in details hereinafter by referring to the following three embodiments.

### First Embodiment

The conventional spacer in a MOSFET is formed by depositing SiO₂, Si₃N₄, or the combination thereof. However, in the present invention the spacer is formed as follows. According to the present invention, a SiO₂ layer may be deposited on the gate and the semiconductor substrate, the SiO₂ layer is doped with carbon during depositing to form a SiO₂ layer with a relatively low dielectric constant, and the excessive portion of the SiO₂ layer with a low dielectric constant is removed by etching, so as to form the low-K gate spacer 103 shown in FIG. 1 or the low-K gate spacer 1 shown in FIG. 3. In another embodiment of the present invention, a SiO₂/Si₃N₄ layer is deposited on the gate and the semiconductor substrate, the SiO₂/Si₃N₄ layer is doped with carbon during deposition to form a SiO₂/Si₃N₄ layer with a relatively low dielectric constant, and the excessive part of the SiO₂/Si₃N₄ layer with a low dielectric constant is removed by etching, so as to form the gate spacer 103 shown in FIG. 1 or the gate spacer 1 shown in FIG. 3. In another embodiment of the present invention, it is also possible to form the spacer by Si₃N₄ doped with carbon.

Any conventional process for incorporating carbon component into SiO₂, Si₃N₄, SiO₂+Si₃N₄ spacer can be applied to the process of carbon doping. In an example, the molar ratio of carbon is 1%-50%. In embodiments of the present invention, preferred processes may include forming carbon-containing SiO₂ by reactions between tetramethylsilane and carbon dioxide gas, forming carbon-containing Si₃N₄ by reaction between tetramethylsilane and ammonia, and changing the ratio of carbon in SiO₂ or Si₃N₄ by adjusting the reaction ratio between tetramethylsilane and carbon dioxide or ammonia. As a result, a large quantity of carbon is introduced into the spacer of SiO₂, Si₃N₄, or the combination thereof, so that the K-value of the spacer material is decreased to 3.0 or less. In this way, the low-K gate spacer 103 shown in FIG. 1 or the low-K gate spacer 1 shown in FIG. 3 is formed.

### Second Embodiment

Specifically, step 3 may comprise the steps of:

step 31: forming a microporous carbon-doped low-K dielectric inner layer on the gate and the semiconductor substrate by deposition, and forming a first spacer layer from the inner layer by a self-aligning etching process, and

step 32: depositing on the first spacer layer an outer layer of SiO₂, Si₃N₄, or the combination thereof, and forming a second spacer layer from the outer layer by a self-aligning etching process.

It can be seen from step 31 and step 32 mentioned above that the low-K spacer comprises an inner layer and an outer layer to reduce the coupling interference in MOSFET. That is, a microporous carbon doped silicon dioxide (or Carbon Doped Oxide, CDO for short) with an ultra low dielectric constant (ULK) (e.g. k is 2.5) is applied as the inner spacer layer. Besides, in order to impart the spacer a certain physical strength, prevent the subsequently formed films from influencing the properties of the spacer, and avoid the following issue of metal electromigration, it is required to form a relatively dense dielectric layer on the outside of the inner spacer layer. In preferred embodiments of the present invention, the conventional SiO₂, Si₃N₄, or the combination thereof, or the carbon doped SiO₂, Si₃N₄, or the combination thereof can further be applied as the outer spacer layer, thus reducing the whole dielectric constant (2.5<k<3.0).

Specifically, step 31 may comprise the steps of:

step 311a: depositing on the gate and the semiconductor substrate a carbon doped low-K dielectric thin film comprising a pore-forming agent,

step 312a: removing the pore-forming agent in the carbon doped low-K dielectric thin film by ultraviolet (UV) baking, thus forming a microporous carbon doped low-K dielectric layer, and

step 313a: forming an ULK inner spacer layer by a self-aligning etching process.

Here, during forming the ULK inner spacer layer by a self-aligning etching process, since there is a relatively high etching selection ratio between the material of the ULK inner spacer layer and the material of the gate, the top of ULK inner spacer layer may be kept away from that of outer spacer layer by a distance, usually 1/10-½ of the gate height. This has the following advantages. On one hand, it is possible to prevent the following processes from influencing the morphology of the gate and SiO₂ thin layer. Namely, the outer spacer layer can enclose the ULK inner spacer layer completely. On the other hand, the following issue of metal electromigration can be avoided.

In another embodiment of the present invention in which an inner and outer spacer layer are applied, the inner layer is amorphous carbon (AC) with a k-value of 2.5-3.0. In order to impart the spacer a certain physical strength, prevent the subsequently formed films from influencing the properties of the spacer, and avoid the following issue of metal electromigration, it is required to form a relatively dense dielectric layer on the outside of the inner layer. Therefore, the conventional SiO₂, Si₃N₄, or the combination thereof, or the carbon doped SiO₂, Si₃N₄, or the combination thereof is further applied as the outer spacer layer, thus reducing the whole dielectric constant (2.5<k<3.0)

In other words, step 31 may particularly comprise the steps of:

step 311b: depositing an amorphous carbon thin film on the gate and the semiconductor substrate, and

step 312b: forming an amorphous carbon inner spacer layer by a self-aligning etching process.

This embodiment is similar with the embodiment described above in which the ULK inner spacer layer is formed by a self-aligning etching process. In particular, during forming the AC inner spacer layer by a self-aligning etching, since there is a relatively high etching selection ratio between the material of the AC inner spacer layer and the material of the gate, the top of AC inner spacer layer may be kept away from that of outer spacer layer by a distance, usually 1/10-½ of the gate height. This has the advantage of, apart from preserving morphology of the gate and avoiding the following issue of metal electromigration, preventing the following ashing process from influencing the AC inner spacer layer.

The above step 32 is to form a relatively dense dielectric layer on the outside of the inner spacer layer. Specifically, step 32 may comprise the steps of:

step 321: depositing a conventional SiO₂, Si₃N₄, or the combination thereof, or a carbon doped thin film of SiO₂ or Si₃N₄ on the outside of the inner spacer layer, and

step 322: forming an outer spacer layer by a self-aligning etching process.

To sum up, the present invention provides a method for preparing spacer to reduce coupling interference in MOSFET, which dopes the spacer material with carbon during deposition, so that the dielectric constant of the spacer material is significantly decreased. As a result, the effect in which the electric field at the edge of the source/drain influences the channel through capacitive coupling of spacer can be reduced in a CMOSFET with a thick high-K gate, the short channel effect in a CMOSFET with a thick high-K gate dielectric layer can be effectively suppressed, and the performance of the CMOS device can be improved. Furthermore, the method is simple and convenient to carry out.

It is particularly worth mentioning that, in case that the present invention is applied to prepare a non-volatile memory cell of a CMOS device, regarding the coupling interference in a non-volatile memory, carbon is doped while depositing the spacer material layer. As compared with the non-volatile memory in the prior art, the dielectric constant of the spacer material can be decreased significantly. For example, upon doping SiO₂ with carbon, the relative dielectric constant can be decreased to 2.7 or less. In addition, since the present invention manages to eliminate the coupling interference in a non-volatile memory, it is possible to omit the IRO-related additional circuits, so that the design of memory circuit is efficiently simplified, and the integration level of the non-volatile memory as well as the reading/writing speed of the memory can be improved.

The foregoing embodiments only relate to preferred embodiments of the present invention. The skilled in the art would recognize that these embodiments are by no means intended to limit the scope of patent protection the present invention, and that all of the structural equivalents in light of the description and accompanying drawings should fall within the scope of the present invention.

1. A method for preparing spacer to reduce coupling interference in MOSFET, the spacer is included in a function unit of a CMOS device, the method comprises the steps of:
step 1: forming a gate oxide layer on the semiconductor substrate,
step 2: forming a gate on the gate oxide layer, and
step 3: depositing a low-K dielectric material on the gate and the semiconductor substrate, and doping with carbon during deposition to form a carbon-containing low-K dielectric layer, and then forming the spacer by an etching process.

2. The method as claimed in claim 1, wherein, the low-K dielectric layer of the spacer is formed by SiO₂, Si₃N₄, or the combination thereof, and SiO₂ or Si₃N₄ is doped with carbon.

3. The method as claimed in claim 1, wherein, the low-K dielectric layer of the spacer has a relative dielectric constant of 1.8-3.5.

4. The method as claimed in claim 1, wherein, the step 3 particularly comprises the steps of:
step 31: forming a microporous carbon-doped low-K dielectric inner layer on the gate and the semiconductor substrate by deposition, and forming a first spacer layer from the inner layer by a self-aligning etching process, and
step 32: depositing on the first spacer layer an outer layer of SiO₂, Si₃N₄, or the combination thereof, and forming a second spacer layer from the outer layer by a self-aligning etching process.

5. The method as claimed in claim 4, wherein, the inner layer is formed by SiO₂, Si₃N₄, or the combination thereof, and SiO₂ or Si₃N₄ is doped with carbon.

6. The method as claimed in claim 4, wherein, the inner layer is formed by amorphous carbon.

7. The method as claimed in claim 4, wherein, the top of the inner spacer layer formed in the step 31 is lower than that of the outer spacer layer formed in the step 32.

8. The method as claimed in claim 4, wherein, the outer layer of the low-K dielectric layer is formed by SiO₂, Si₃N₄, or the combination thereof.

9. The method as claimed in claim 4, wherein, the outer layer of the spacer in the low-K dielectric layer is formed by SiO₂, Si₃N₄, or the combination thereof, and SiO₂ or Si₃N₄ is doped with carbon.

10. The method as claimed in claim 1, wherein, the material of the gate oxide layer comprises any one of HfO₂, ZrO₂, Al₂O₃, or the combination thereof.

11. The method as claimed in claim 1, wherein, the function unit is a non-volatile memory cell of a floating gate type; wherein the gate comprises from bottom to top a tunneling oxide layer, a floating gate layer, a charge blocking layer, and a control gate layer.

12. The method as claimed in claim 1, wherein, the function unit is a non-volatile memory cell of a trap charge capturing type; wherein the gate comprises from bottom to top a tunneling oxide layer, a charge trapping layer, a charge blocking layer, and a control gate layer.

13. The method as claimed in claim 1, wherein, the gate oxide layer is a thick high-K gate dielectric layer.
